(19) United States
(12) Patent Application Publication
(10) Pub. No.: US 2025/0324659 A1
(43) Pub. Date: Oct. 16, 2025

(54) SEMICONDUCTOR DEVICE AND MANUFACTURING METHOD THEREOF

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Ko HYODO, Nonoichi Ishikawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/820,584

(22) Filed: Aug. 30, 2024

(30) Foreign Application Priority Data
Apr. 15, 2024 (JP) 2024-065551

(51) Int. Cl. H01L 29/78; H01L 21/28; H01L 29/49; H01L 29/51; H01L 29/66

(52) U.S. Cl. CPC H10D 30/668; H01L 21/28079; H10D 30/0297; H10D 64/666; H10D 64/68

(57) ABSTRACT

A semiconductor device according to one embodiment includes a semiconductor part including a first semiconductor layer, a second semiconductor layer located on the first semiconductor layer, and a third semiconductor layer located in a first trench of the second semiconductor layer, a first electrode located on a back surface of the first semiconductor layer, a first metallic film in contact with the second semiconductor layer in the first trench, a second metallic film in contact with the third semiconductor layer and the first metallic film in the first trench, and a second electrode in contact with the second metallic film in the first trench. The first metallic film includes a high work function metal, and the second metallic film includes a low work function metal having a lower work function than that of the first metallic film.

### CROSS-REFERENCE TO RELATED APPLICATIONS

This application is based upon and claims the benefit of priority from Japanese Patent Application No. 2024-065551, filed on Apr. 15, 2024; the entire contents of which are incorporated herein by reference.

### FIELD

The embodiments of the present invention relate to a semiconductor device and a manufacturing method thereof.

### BACKGROUND

In semiconductor devices such as a MOSFET (Metal-Oxide-Semiconductor Field-Effect Transistor) having a trench gate, a structure in which a source electrode and a semiconductor layer are electrically connected to each other with a trench contact is known.

In a semiconductor device having the trench contact structure described above, decrease of contact resistance is demanded to decrease on-resistance.

### BRIEF DESCRIPTION OF THE DRAWINGS

FIG. 1 is a sectional view of a semiconductor device according to a first embodiment;

FIG. 2 is a sectional view for explaining a process of forming a gate electrode, a third electrode, and an insulating film in each of second trenches;

FIG. 3 is a sectional view for explaining a process of forming a first trench on a second semiconductor layer;

FIG. 4 is a sectional view for explaining a process of forming a PSG film on an inner surface of the first trench;

FIG. 5 is a sectional view for explaining a process of forming a third semiconductor layer;

FIG. 6 is a sectional view for explaining a process of removing the PSG film;

FIG. 7 is a sectional view for explaining a process of etching the first trench to a deeper position;

FIG. 8 is a sectional view for explaining a process of forming a first metallic film on the inner surface of the first trench;

FIG. 9 is a sectional view for explaining a process of embedding an insulating film in the first trench;

FIG. 10 is a sectional view for explaining a process of etching back the insulating film;

FIG. 11 is a sectional view for explaining a process of removing a part of the first metallic film;

FIG. 12 is a sectional view for explaining a process of removing the insulating film;

FIG. 13 is a sectional view for explaining a process of forming a second metallic film and a third semiconductor layer including a silicide;

FIG. 14 is a sectional view for explaining a process of embedding a second electrode in the first trench;

FIG. 15 is a sectional view of a semiconductor device according to a comparative example;

FIG. 16 is a sectional view of a semiconductor device according to a second embodiment;

FIG. 17 is a sectional view for explaining a process of forming the first metallic film in the first trench;

FIG. 18 is a sectional view for explaining a process of etching back the first metallic film;

FIG. 19 is a sectional view for explaining a process of forming the second metallic film;

FIG. 20 is a sectional view for explaining a process of forming a third semiconductor layer including a silicide; and

FIG. 21 is a sectional view for explaining a process of embedding the second electrode in the first trench.

### DETAILED DESCRIPTION

Embodiments will now be explained with reference to the accompanying drawings. The present invention is not limited to the embodiments.

A semiconductor device according to one embodiment includes a semiconductor part including a first semiconductor layer, a second semiconductor layer located on the first semiconductor layer, and a third semiconductor layer located in a first trench of the second semiconductor layer, a first electrode located on a back surface of the first semiconductor layer, a first metallic film in contact with the second semiconductor layer in the first trench, a second metallic film in contact with the third semiconductor layer and the first metallic film in the first trench, and a second electrode in contact with the second metallic film in the first trench. The first metallic film includes a high work function metal, and the second metallic film includes a low work function metal having a lower work function than that of the first metallic film.

### First Embodiment

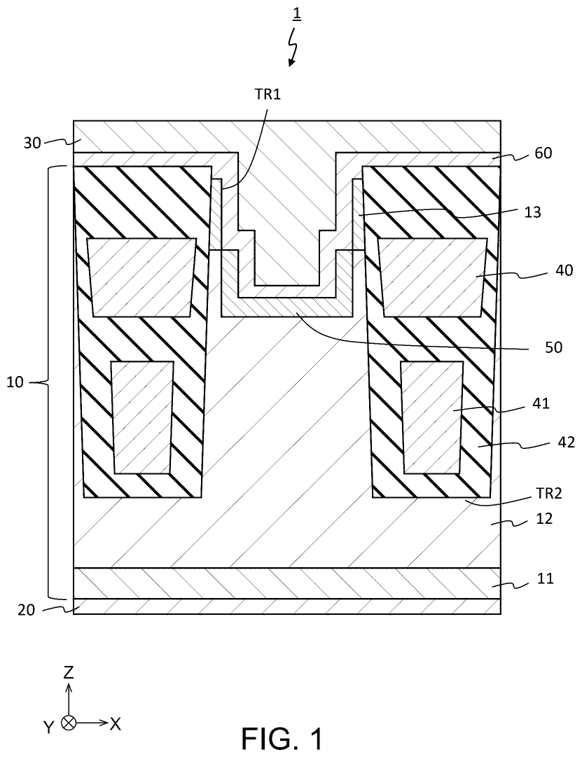

FIG. 1 is a sectional view of a semiconductor device according to a first embodiment. In the following explanations, arrangement and configurations of components of the semiconductor device may be described by use of an X-axis, a Y-axis, and a Z-axis illustrated in each drawing. The X-axis, the Y-axis, and the Z-axis are orthogonal to one another and represent an X direction, a Y direction, and a Z direction, respectively. The Z direction is also described as upward and the direction opposite thereto is also described as downward. In the present embodiment, the X direction and the Y direction correspond to a first direction and a third direction and represent in-plane directions parallel to a front surface (or a back surface) of the semiconductor device 1. The Z direction corresponds to a second direction and represents an out-plane direction orthogonal to the front surface (or the back surface) of the semiconductor device 1.

Notations p and p⁺ indicate p-type impurity concentrations being higher in this order. Notations n⁻, n, and n⁺ indicate n-type impurity concentrations being higher in this order.

The impurity concentration can be measured by SIMS (Secondary Ion Mass Spectrometry), for example. The relative level of the impurity concentration can be also determined by, for example, a level of the carrier concentration obtained by SCM (Scanning Capacitance Microscopy). A distance such as a depth in a semiconductor region can be obtained by SIMS, for example.

The semiconductor device 1 illustrated in FIG. 1 is a low-voltage Schottky MOSFET. The semiconductor device 1 includes a semiconductor part 10, a first electrode 20, a second electrode 30, a gate electrode 40, a third electrode 41, a first metallic film 50, and a second metallic film 60.

The material of the semiconductor part 10 is silicon, for example. The first electrode 20 is located on the back surface of the semiconductor part 10. Meanwhile, the second electrode 30 is located on the front surface of the semiconductor part 10. The first electrode 20 is a drain electrode. The second electrode 30 is a source electrode. The first electrode 20 is made of a metallic material including, for example, nickel (Ni), aluminum (Al), or the like. Meanwhile, the second electrode 30 is made of a metallic material including tungsten (W) and aluminum (Al), for example.

The semiconductor part 10 includes a first semiconductor layer 11, a second semiconductor layer 12, and a third semiconductor layer 13. The conductivity types of these semiconductor layers are the n type. Each of the semiconductor layers is described below.

The first semiconductor layer 11 is an n⁺-type substrate layer. The back surface of the first semiconductor layer 11 is in contact with the first electrode 20. The second semiconductor layer 12 is in contact with the front surface of the first semiconductor layer 11.

The second semiconductor layer 12 is an n⁻-type drift layer. The concentration of n-type impurities included in the second semiconductor layer 12 is lower than that of n-type impurities included in the first semiconductor layer 11. The third semiconductor layer 13, a first trench TR1, second trenches TR2, the first metallic film 50, and the second metallic film 60 are located in the second semiconductor layer 12.

The third semiconductor layer 13 is an n⁺-type source layer. The concentration of n-type impurities included in the third semiconductor layer 13 is higher than that of the n-type impurities included in the second semiconductor layer 12. A silicide is also included in the third semiconductor layer 13. In the present embodiment, titanium silicide (TiSi) is included in the third semiconductor layer 13. However, the silicide included in the third semiconductor layer 13 is not limited to titanium silicide. The third semiconductor layer 13 is in contact with the second metallic film 60.

The first trench TR1 is a so-called contact trench. In the present embodiment, the first trench TR1 is arranged between two second trenches TR2 arrayed in the X direction. The depth of the first trench TR1 from the front surface of the semiconductor part 10 is smaller than the depth of each of the second trenches TR2 from the front surface of the semiconductor part 10. The third semiconductor layer 13, the first metallic film 50, the second metallic film 60, and the second electrode 30 are located in the first trench TR1.

The first metallic film 50 is in contact with the second semiconductor layer 12 in a lower part of the first trench TR1. The material of the first metallic film 50 is a high work function metal. In the present embodiment, the first metallic film 50 is made of platinum (Pt). However, the material of the first metallic film 50 is not limited to platinum and may be other high work function metals such as Ni and cobalt (Co).

The second metallic film 60 extends from an upper part of the first trench TR1 to the lower part thereof. The second electrode 30 also extends from the upper part of the first trench TR1 to the lower part thereof. Accordingly, the second metallic film 60 is interposed between the first metallic film 50 and the second electrode 30 in the lower part of the first trench TR1. The second metallic film 60 is also interposed between the third semiconductor layer 13 and the second electrode 30 in a lateral part of the first trench TR1.

The second metallic film 60 has, for example, a two-layer structure including a metallic layer and a barrier metal layer. This metallic layer is in contact with the first metallic film 50 and the third semiconductor layer 13. This barrier metal layer is stacked on the metallic layer. The material of the metallic layer is titanium (Ti), for example. Meanwhile, the material of the barrier metal layer is titanium nitride (TiN). However, the materials of the metallic layer and the barrier metal layer are not limited to titanium and titanium nitride and it suffices that the materials are low work function metals having a lower work function than that of the first metallic film 50.

The gate electrode 40, the third electrode 41, and an insulating film 42 are located in each of the second trenches TR2. An internal structure of the second trenches TR2 is described below.

The gate electrode 40 and the third electrode 41 are arranged away from each other in the Z direction. Specifically, the gate electrode 40 is arranged in an upper part of each of the second trenches TR2 while the third electrode 41 is arranged in a lower part of each of the second trenches TR2.

The third electrodes 41 are so-called field plates. The third electrodes 41 are electrically connected to the second electrode 30. Each of the third electrodes 41 is electrically insulated from the gate electrode 40 by the insulating film 42. The insulating film 42 is a silicon dioxide film (SiO₂), for example.

The insulating film 42 also functions as a gate dielectric film that electrically insulates the gate electrode 40 from the semiconductor part 10. The second semiconductor layer 12 is provided to be opposed to the gate electrode 40 with the gate dielectric film interposed therebetween. The third semiconductor layer 13 is in contact with the gate dielectric film.

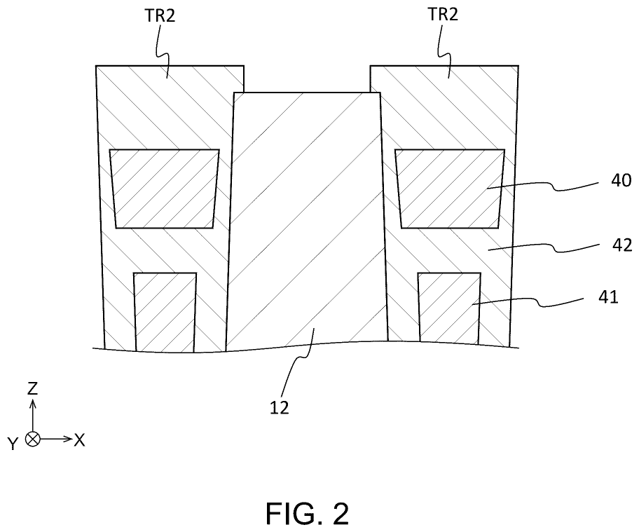

A manufacturing method of the semiconductor device 1 according to the present embodiment is explained below with reference to FIGS. 2 to 14. Principal manufacturing processes are described here.

First, as illustrated in FIG. 2, the second trenches TR2 are formed on the second semiconductor layer 12 stacked on the first semiconductor layer 11, and the gate electrode 40, the third electrode 41, and the insulating film 42 are formed in each of the second trenches TR2. The gate electrode 40 and the third electrode 41 are made of polysilicon, for example.

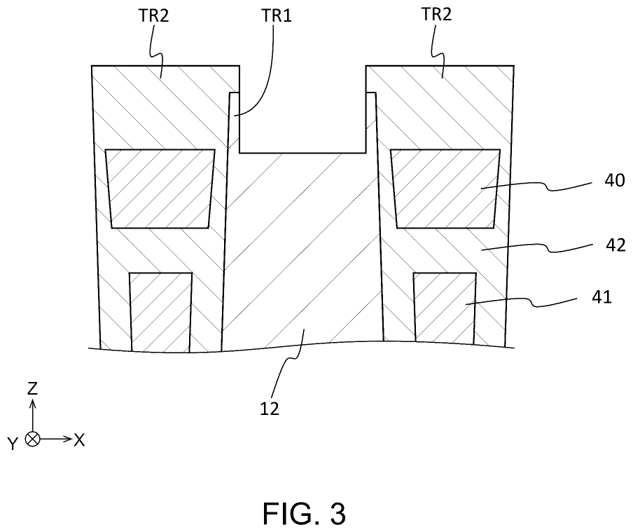

Next, as illustrated in FIG. 3, the first trench TR1 is formed on the second semiconductor layer 12. The first trench TR1 is formed by RIE (Reactive Ion Etching), for example. However, in this process, formation of the first trench TR1 is interrupted at a time when the first trench TR1 reaches a depth where the third semiconductor layer 13 is to be formed, in other words, the same height position level as the upper surfaces of the gate electrodes 40.

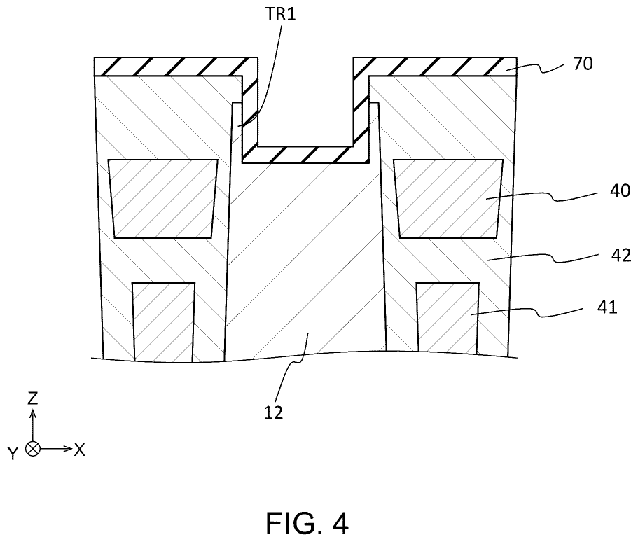

Subsequently, as illustrated in FIG. 4, a PSG (Phosphorous Silicate Glass) film 70 is formed on an inner surface of the first trench TR1. The PSG film 70 can be formed by CVD (Chemical Vapor Deposition), for example.

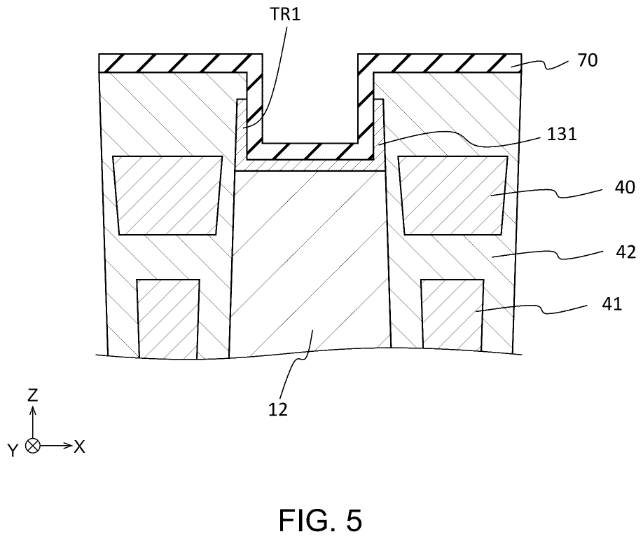

Next, the PSG film 70 is thermally treated. With this thermal treatment, n-type impurities included in the PSG film 70 thermally diffuse to the second semiconductor layer 12. As a result, a third semiconductor layer 131 is formed on a part in contact with the PSG film 70, that is, on the inner surface of the first trench TR1 as illustrated in FIG. 5.

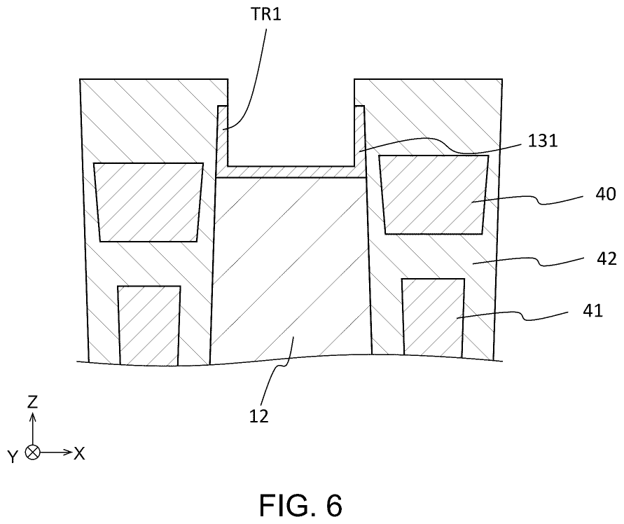

Next, as illustrated in FIG. 6, the PSG film 70 is removed. As a result, the third semiconductor layer 131 is exposed. The formation method of the third semiconductor layer 131 is not limited to the thermal diffusion from the PSG film 70 described above. For example, the third semiconductor layer 131 may be formed by implantation of ions of n-type impurities into the second semiconductor layer 12.

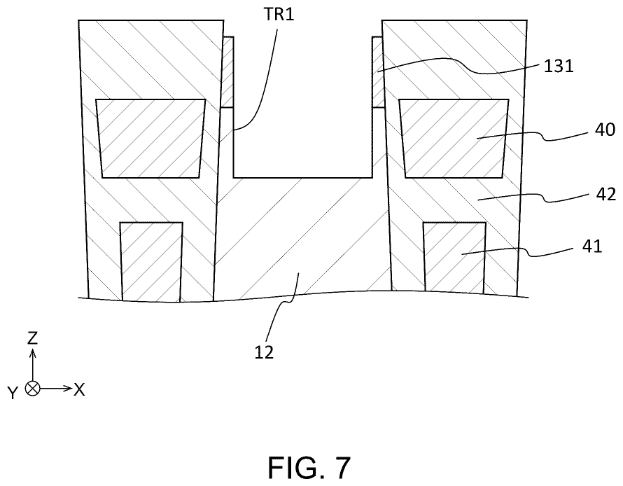

Subsequently, as illustrated in FIG. 7, the first trench TR1 is etched to a deeper position by RIE, for example. In this process, the depth of the first trench TR1 reaches a depth where the first metallic film 50 is to be formed, in other words, the same height position level as that of the bottom surfaces of the gate electrodes 40.

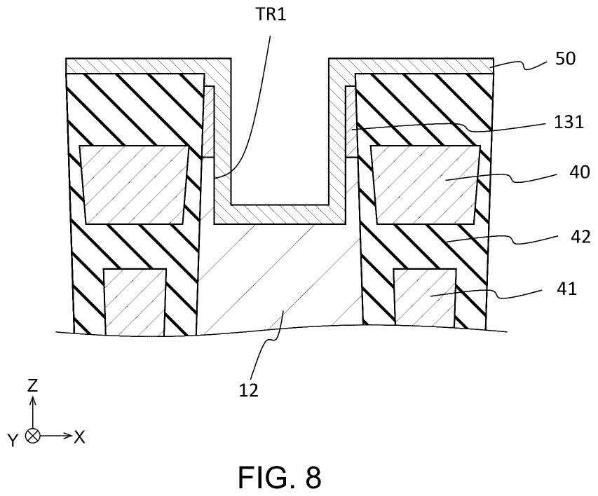

Subsequently, as illustrated in FIG. 8, the first metallic film 50 is formed on the inner surface of the first trench TR1. At that time, the third semiconductor layer 131 is covered by the first metallic film 50.

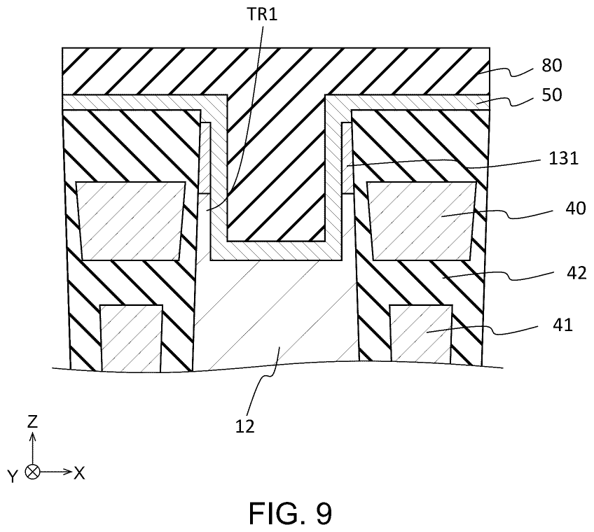

Next, as illustrated in FIG. 9, an insulating film 80 is embedded in the first trench TR1. The insulating film 80 is formed using silicon nitride or TEOS (Tetra Ethoxy Silane), for example. It is desirable that the insulating film 80 is formed by, for example, a low-temperature formation method such as plasma CVD, plasma ALD (Atomic Layer Deposition), or SOG (Spin On Glass). With use of these formation methods, formation of platinum silicide (PtSi) on the third semiconductor layer 131 can be avoided.

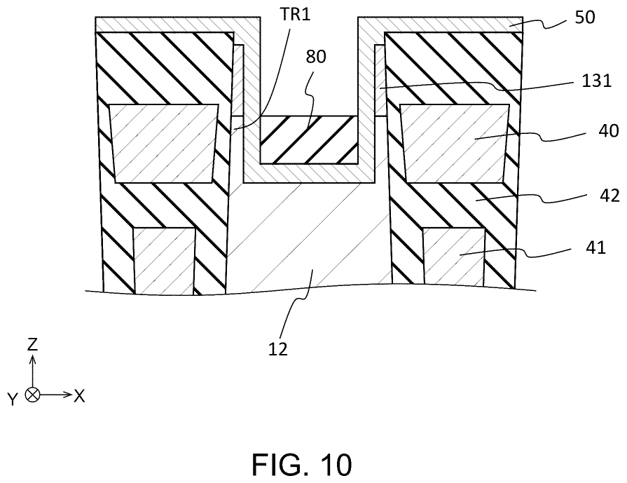

Next, as illustrated in FIG. 10, the insulating film 80 is etched back. In this process, the insulating film 80 is etched back to cause the upper surface of the insulating film 80 in the first trench TR1 to be at substantially the same height position level as that of the bottom surface of the third semiconductor layer 131.

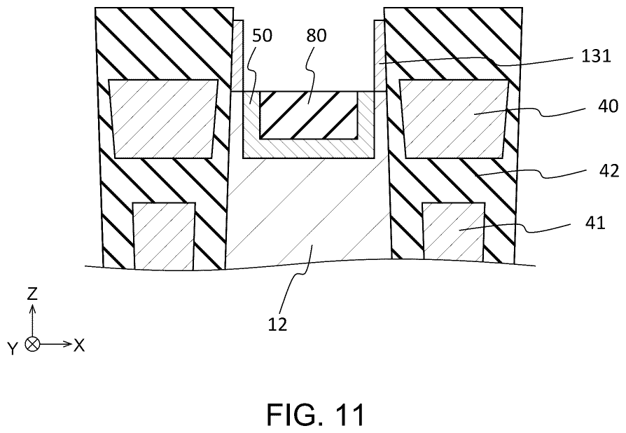

Subsequently, as illustrated in FIG. 11, a part of the first metallic film 50 formed on the side surface of the first trench TR1, in other words, a part not in contact with the insulating film 80 is removed. The first metallic film 50 is etched with, for example, a solution such as aqua regia.

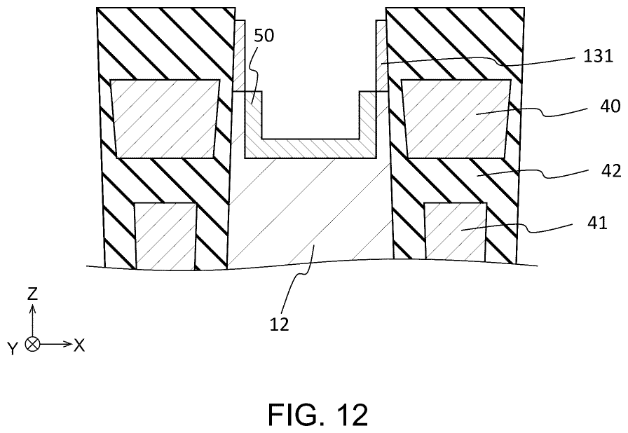

Next, as illustrated in FIG. 12, the insulating film 80 is removed. Accordingly, the first metallic film 50 is exposed.

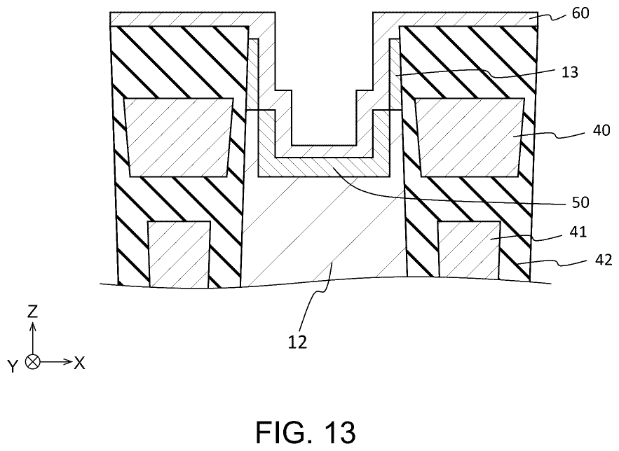

Next, as illustrated in FIG. 13, the second metallic film 60 is formed to cover the third semiconductor layer 131 and the first metallic film 50 in the first trench TR1. Subsequently, the third semiconductor layer 13 including a silicide is formed by thermally treating the second metallic film 60.

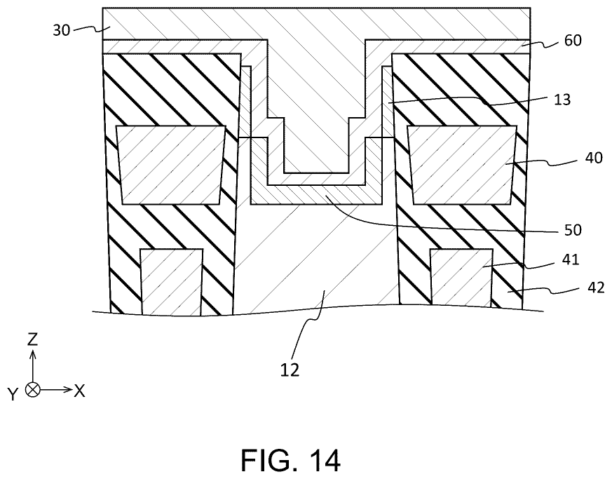

Finally, as illustrated in FIG. 14, the second electrode 30 is embedded in the first trench TR1. Separately from this process, the first electrode 20 is formed on the back surface of the first semiconductor layer 11.

A comparative example to be compared with the present embodiment is explained below.

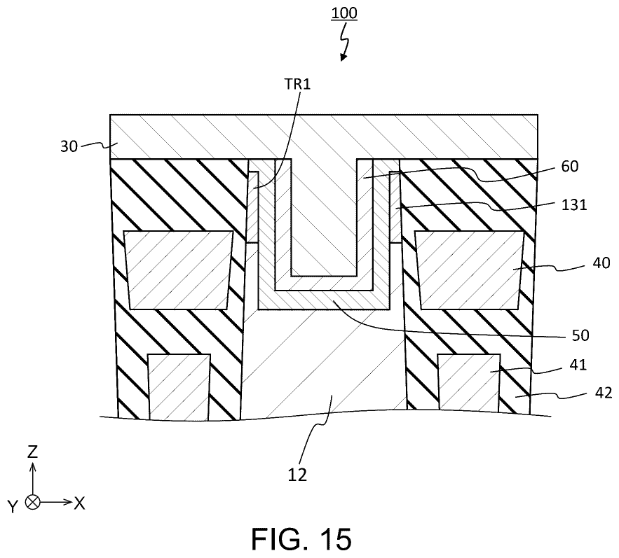

FIG. 15 is a sectional view of a semiconductor device according to a comparative example. In FIG. 15, constituent elements identical to those of the semiconductor device 1 described above are denoted by like reference characters and redundant explanations thereof are omitted.

In a semiconductor device 100 according to the present comparative example, the first metallic film 50 including a high work function metal is interposed between the third semiconductor layer 131 and the second metallic film 60. That is, a Schottky junction is formed in both an upper mesa region being a contact region between the third semiconductor layer 131 and the first metallic film 50, and a lower mesa region being a contact region between the first metallic film 50 and the second semiconductor layer 12.

In the semiconductor device 100 having the structure described above, the contact resistance lowers as the n-type impurity concentration in the third semiconductor layer 131 becomes higher. However, as illustrated in FIG. 15, the third semiconductor layer 131 is formed thin on the sidewall of the first trench TR1. Accordingly, a process of locally implanting a high concentration of n-type impurities into the third semiconductor layer 131 is highly difficult.

To solve this problem, in the present embodiment, the third semiconductor layer 13 is in contact with the second metallic film 60 including a low work function metal. As a result, an ohmic junction with the third semiconductor layer 13 and the second metallic film 60 is formed in the upper mesa region, and a Schottky junction between the first metallic film 50 including a high work function metal and the second semiconductor layer 12 is formed in the lower mesa region.

Therefore, according to the present embodiment, the contact resistance can be decreased by a method other than a method of increasing the n-type impurity concentration in the third semiconductor layer 131.

Further, when the third semiconductor layer 131 including a high concentration of n-type impurities is formed by thermal diffusion of the PSG film 70 as in the present embodiment, the local ion implantation process becomes unnecessary.

### Second Embodiment

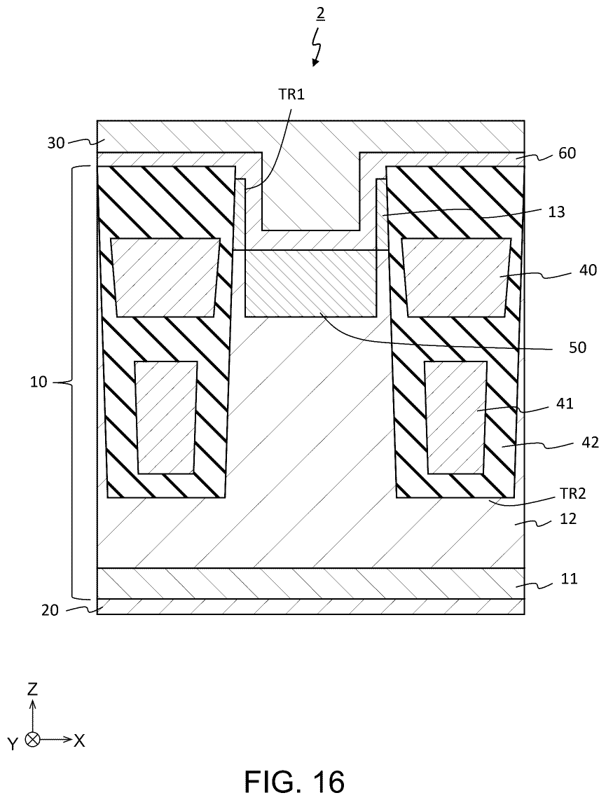

FIG. 16 is a sectional view of a semiconductor device according to a second embodiment. In FIG. 16, constituent elements identical to those of the semiconductor device 1 according to the first embodiment described above are denoted by like reference characters and redundant explanations thereof are omitted. In the semiconductor device 1 according to the first embodiment describe above, the second metallic film 60 and the second electrode 30 extend from the upper part of the first trench TR1 to the lower part thereof.

In contrast thereto, in a semiconductor device 2 according to the second embodiment, the first metallic film 50 is embedded in the lower part of the first trench TR1 as illustrated in FIG. 16. Accordingly, the second metallic film 60 and the second electrode 30 terminates in the upper part of the first trench TR1.

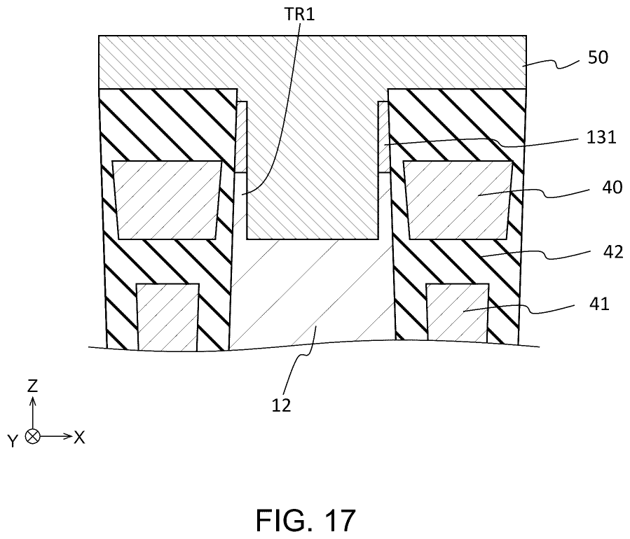

A manufacturing method of the semiconductor device 2 according to the present embodiment is explained below with reference to FIGS. 17 to 21. Since processes until the third semiconductor layer 131 is formed by thermal diffusion of the PSG film 70 (see FIGS. 2 to 7) are the same as those in the first embodiment, explanations thereof are omitted.

In the present embodiment, after the third semiconductor layer 131 is formed and the first trench TR1 is etched to a deeper position, the first metallic film 50 is formed in the first trench TR1 as illustrated in FIG. 17. At that time, the first trench TR1 is filled with the first metallic film 50.

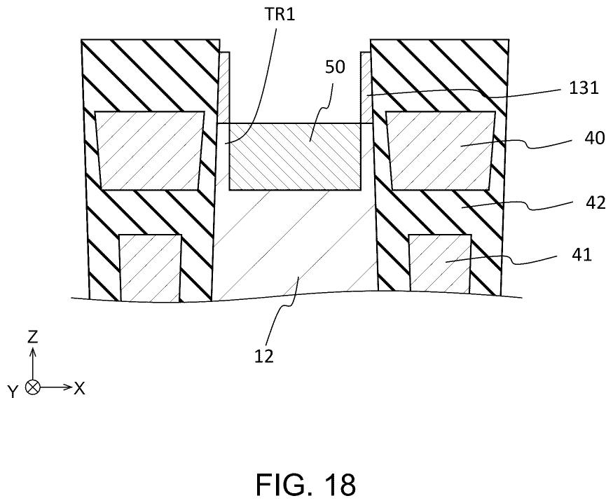

Next, as illustrated in FIG. 18, the first metallic film 50 is etched back. In the present embodiment, the first metallic film 50 is etched back to cause the upper surface of the first metallic film 50 in the first trench TR1 to be at substantially the same height position level as the upper surfaces of the gate electrodes 40.

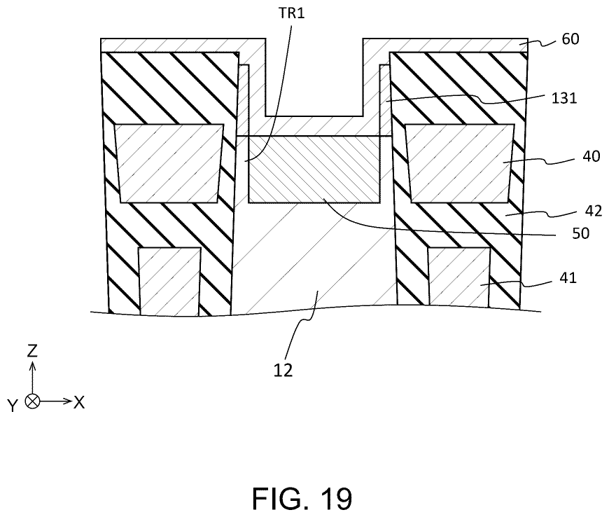

Next, as illustrated in FIG. 19, the second metallic film 60 is formed to cover the third semiconductor layer 131 and the first metallic film 50 in the first trench TR1.

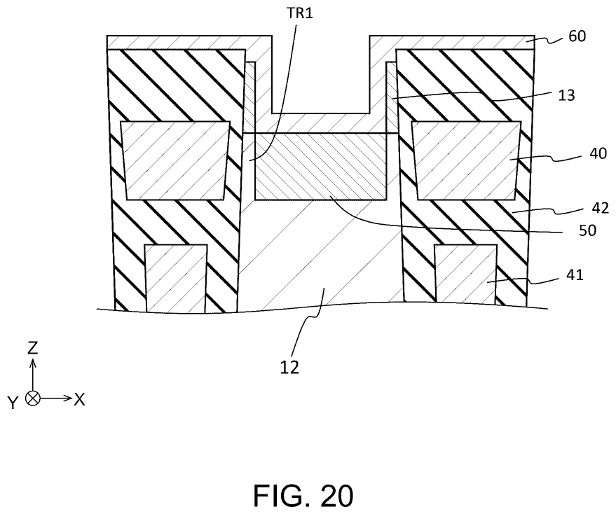

Subsequently, the second metallic film 60 is thermally treated. Accordingly, the third semiconductor layer 13 including a silicide is formed as illustrated in FIG. 20.

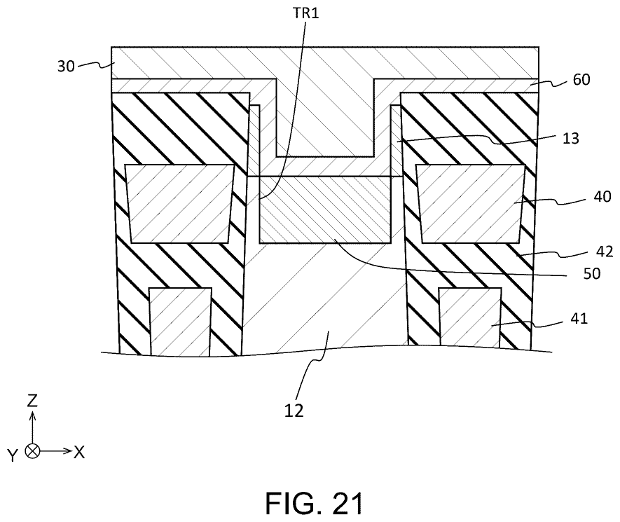

Finally, as illustrated in FIG. 21, the second electrode 30 is embedded in the first trench TR1. Separately from this process, the first electrode 20 is formed on the back surface of the first semiconductor layer 11.

Also in the present embodiment described above, an ohmic junction between the third semiconductor layer 13 and the second metallic film 60 is formed in the upper mesa region and a Schottky junction between the first metallic film 50 and the second semiconductor layer 12 is formed in the lower mesa region, similarly in the first embodiment.

Therefore, according to the present embodiment, the contact resistance can be decreased by a method other than a method of increasing the n-type impurity concentration in the third semiconductor layer 131 similarly in the first embodiment. Further, also in the present embodiment, when the third semiconductor layer 131 including a high concentration of n-type impurities is formed by thermal diffusion of the PSG film 70, the local ion implantation process becomes unnecessary.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a semiconductor part including a first semiconductor layer, a second semiconductor layer located on the first semiconductor layer, and a third semiconductor layer located in a first trench of the second semiconductor layer;
a first electrode located on a back surface of the first semiconductor layer;
a first metallic film in contact with the second semiconductor layer in the first trench;
a second metallic film in contact with the third semiconductor layer and the first metallic film in the first trench; and
a second electrode in contact with the second metallic film in the first trench, wherein
the first metallic film comprises a high work function metal, and
the second metallic film comprises a low work function metal having a lower work function than that of the first metallic film.

2. The device of claim 1, wherein the third semiconductor layer comprises a silicide.

3. The device of claim 1, wherein
the third semiconductor layer is located in an upper part of the first trench, and
the first metallic film is located in a lower part of the first trench.

4. The device of claim 3, wherein the first metallic film and the second electrode extend from the upper part of the first trench to the lower part thereof.

5. The device of claim 3, wherein
the first metallic film and the second electrode terminate in the upper part of the first trench, and
the first metallic film is embedded in the lower part of the first trench.

6. The device of claim 1, wherein
the first trench is arranged between two second trenches arrayed in the second semiconductor layer, and
a gate electrode, a third electrode electrically connected to the second electrode, and an insulating film electrically insulating the gate electrode and the second electrode from each other are located in each of the second trenches.

7. The device of claim 2, wherein the silicide is titanium silicide (TiSi), the high work function metal is platinum (Pt), and the low work function metal is titanium (Ti).

8. The device of claim 1, wherein each of the second semiconductor layer and the third semiconductor layer comprises n-type impurities, a concentration of n-type impurities comprised in the third semiconductor layer is higher than that of n-type impurities comprised in the second semiconductor layer.

9. A manufacturing method of a semiconductor device, the method comprising:
forming a first trench on a second semiconductor layer formed on a first semiconductor layer;
sequentially forming, in the first trench, a third semiconductor layer, a first metallic film being in contact with the second semiconductor layer and comprising a high work function metal, and a second metallic film being in contact with the third semiconductor layer and the first metallic film and comprising a low work function metal having a lower work function than that of the first metallic film; and
forming a first electrode on a back surface of the first semiconductor layer as well as forming a second electrode in contact with the second metallic film in the first trench.

10. The method of claim 9, comprising
forming a PSG (Phosphorous Silicate Glass) film on an inner surface of the first trench, and
forming the third semiconductor layer by thermally treating the PSG film.

11. The method of claim 9, wherein the third semiconductor layer comprises a silicide.

12. The method of claim 9, comprising
forming the third semiconductor layer in an upper part of the first trench, and
forming the first metallic film in a lower part of the first trench.

13. The method of claim 12, wherein the first metallic film and the second electrode extend from the upper part of the first trench to the lower part thereof.

14. The method of claim 12, wherein
the first metallic film and the second electrode terminate in the upper part of the first trench, and
the first metallic film is embedded in the lower part of the first trench.

15. The method of claim 9, wherein
the first trench is formed between two second trenches arrayed in the second semiconductor layer, and
a gate electrode, a third electrode electrically connected to the second electrode, and an insulating film electrically insulating the gate electrode and the second electrode from each other are formed in each of the second trenches.

16. The method of claim 11, wherein the silicide is titanium silicide (TiSi), the high work function metal is platinum (Pt), and the low work function metal is titanium (Ti).

17. The method of claim 9, wherein each of the second semiconductor layer and the third semiconductor layer comprises n-type impurities, a concentration of n-type impurities comprised in the third semiconductor layer is higher than that of n-type impurities comprised in the second semiconductor layer.
